(19) United States
(12) Patent Application Publication
(10) Pub. No.: US 2026/0198175 A1
(43) Pub. Date: Jul. 9, 2026

(54) QUANTUM DOT LIGHT EMITTING DEVICE HAVING TOP EMISSION STRUCTURE AND MANUFACTURING METHOD THEREOF

(71) Applicant: Seoul National University R&DB foundation, Seoul (KR)

(72) Inventors: Jeonghun Kwak, Seoul (KR); Taesoo Lee, Seoul (KR); Minhyung Lee, Seoul (KR)

(21) Appl. No.: 18/716,017

(22) PCT Filed: Nov. 2, 2023
(86) PCT No.: PCT/KR2023/017362

§ 371 Date: Mar. 30, 2026

(30) Foreign Application Priority Data
Apr. 20, 2023 (KR) 10-2023-0052016

(51) Int. Cl. H10K 50/858; H10K 50/115; H10K 71/12

(52) U.S. Cl. CPC H10K 50/858; H10K 50/115; H10K 71/12

(57) ABSTRACT

Provided is a quantum dot light emitting device including a first electrode, a second electrode disposed spaced apart from the first electrode, a quantum dot light emitting layer disposed between the first electrode and the second electrode and including quantum dots, a first charge transport layer disposed between the first electrode and the quantum dot light emitting layer, a second charge transport layer disposed between the second electrode and the quantum dot light emitting layer, and a capping layer which is disposed on the second electrode, is formed by a solution process, controls microcavity interference and has a characteristic of a light scattering layer.

### TECHNICAL FIELD

The present invention relates to an optical device and a manufacturing method thereof, and more particularly to a quantum dot light emitting device and a manufacturing method thereof.

### BACKGROUND ART

The quantum dot is a crystalline semiconductor with a size of several to tens of nanometers and may be composed of hundreds to thousands of atoms. Because a quantum dot is very small, it has a large surface area per unit volume, and most atoms exist on the crystal surface. Because these quantum dots have discontinuous energy levels due to the quantum confinement effect, they exhibit optical/electrical characteristics which are different from bulk semiconductors with a continuous energy band.

Recently, research has been conducted to apply quantum dots to various optical and electronic devices. In particular, an interest in quantum dot light emitting devices utilizing the electroluminescence phenomenon of quantum dots is remarkably increasing. The quantum dot light emitting devices may be used as high-efficiency/low-power light emitting devices, and in particular, they are attracting attention as one of the next-generation light emitting devices due to their narrow emission spectrum and easy wavelength control characteristics.

In order to commercialize a self-emitting type quantum dot light emitting device, that is, a self-emitting QLED (quantum dot light emitting device), it may be advantageous to adopt a top emission structure in terms of combination with the backplane, aperture ratio, etc. However, when adopting a top emission structure as a self-emitting QLED structure, there is a problem that the optical characteristics change sensitively depending on the viewing angle. In other words, QLEDs with a top emission structure have a problem in which relatively large changes in emission intensity and spectrum occur depending on the viewing angle due to the optical resonance phenomenon within the device. Accordingly, a method for adjusting viewing angle characteristics by depositing an auxiliary layer of a certain thickness on an upper electrode of a top emission structure QLED was proposed. The auxiliary layer is formed using a deposition process and is mainly composed of an organic material. However, since there are problems that the number of processes are increased and the costs are increasing during the red (R)/green (G)/blue (B) patterning process, the auxiliary layer is formed as a common layer through a single mask process. In this case, it may be difficult to control optimized characteristics for each pixel. In addition, when using an auxiliary layer formed through a deposition process, it is difficult to control the morphology of the auxiliary layer (thin film), it is difficult to expect additional optical effects and improved light extraction effects. As such, since it is difficult to control morphology or thickness for each pixel with the auxiliary layer formed through the existing deposition process, there are various limitations in improving the characteristics of QLED.

### DISCLOSURE OF THE INVENTION

### Technical Problem

The technological object to be achieved by the present invention is to provide a quantum dot light emitting device which may improve optical characteristics according to the viewing angle and at the same time, may increase efficiency due to light scattering by applying a capping layer with multifunctionality formed through a predetermined solution process, and a manufacturing method thereof.

In addition, the technological object to be achieved by the present invention is to provide a quantum dot light emitting device which is advantageous in terms of process difficulty and process cost, and may easily control the thickness and morphology of a capping layer depending on the emission wavelength by applying a capping layer formed through a solution process, and a manufacturing method thereof.

The object to be solved by the present invention is not limited to the objects mentioned above, and other objects not mentioned will be understood by those skilled in the art from the description below.

### Technical Solution

According to one embodiment of the present invention, there is provided a quantum dot light emitting device comprising: a first electrode; a second electrode disposed spaced apart from the first electrode; a quantum dot light emitting layer disposed between the first electrode and the second electrode and including quantum dots; a first charge transport layer disposed between the first electrode and the quantum dot light emitting layer; a second charge transport layer disposed between the second electrode and the quantum dot light emitting layer; and a capping layer which is disposed on the second electrode, is formed by a solution process, controls microcavity interference and has a characteristic of a light scattering layer, wherein the quantum dot light emitting device has a top emission structure which emits light from the quantum dot light emitting layer toward the capping layer.

The capping layer may include a plurality of nanoparticles, and the plurality of nanoparticles may constitute a plurality of nanoparticle clusters.

The plurality of nanoparticles may include at least one of a metal oxide and a non-metal oxide.

The plurality of nanoparticles may include at least one of zinc oxide, zinc magnesium oxide, zinc aluminum oxide, titanium oxide, and silicon oxide.

The capping layer may have a distribution factor (ρ) in a range of about 0.2 to 5, and the distribution factor (ρ) may be defined by an equation ρ=N(A_{cluster}/A_{s-CPL}), wherein in the equation, A_{cluster} may represent an area occupied by the nanoparticle cluster in a cross-sectional region of the capping layer, A_{s-CPL} may represent an area occupied by the entire capping layer corresponding to the cross-sectional region, and N may represent a number of the nanoparticle cluster in the cross-sectional region.

The capping layer may have a normalized scattering intensity in a range of about 1.1 to 1.5.

The capping layer may have a surface roughness (RMS) greater than 0 and less than or equal to 5 nm.

It may further include at least one of a first charge injection layer disposed between the first electrode and the first charge transport layer, and a second charge injection layer disposed between the second electrode and the second charge transport layer.

The quantum dot light emitting layer may include a first quantum dot light emitting portion disposed to correspond to a first pixel region, a second quantum dot light emitting portion disposed to correspond to a second pixel region, and a third quantum dot light emitting portion disposed to correspond to a third pixel region; the capping layer may include a first capping layer portion disposed to correspond to the first pixel region, a second capping layer portion disposed to correspond to the second pixel region, and a third capping layer portion disposed to correspond to the third pixel region, and at least two of the first to third capping layers may have different thicknesses.

According to another embodiment of the present invention, there is provided a manufacturing method of a quantum dot light emitting device comprising: preparing a first electrode; forming a first charge transport layer on the first electrode; forming a quantum dot light emitting layer including quantum dots on the first charge transport layer; forming a second charge transport layer on the quantum dot light emitting layer; forming a second electrode on the second charge transport layer; and forming a capping layer which controls microcavity interference and has a characteristic of a light scattering layer on the second electrode by using a solution process, wherein the quantum dot light emitting device has top emission characteristic which emits light from the quantum dot light emitting layer toward a direction where the capping layer is disposed.

The capping layer may include a plurality of nanoparticles, and the plurality of nanoparticles may constitute a plurality of nanoparticle clusters.

The plurality of nanoparticles may include at least one of a metal oxide and a non-metal oxide.

The plurality of nanoparticles may include at least one of zinc oxide, zinc magnesium oxide, zinc aluminum oxide, titanium oxide, and silicon oxide.

The capping layer may have a distribution factor (ρ) in a range of about 0.2 to 5, and the distribution factor (ρ) may be defined by an equation ρ=N(A_{cluster}/A_{s-CPL}), wherein in the equation, A_{cluster} may represent an area occupied by the nanoparticle cluster in a cross-sectional region of the capping layer, A_{s-CPL} may represent an area occupied by the entire capping layer corresponding to the cross-sectional region, and N may represent a number of the nanoparticle cluster in the cross-sectional region.

The capping layer may have a normalized scattering intensity in a range of about 1.1 to 1.5.

The capping layer may have a surface roughness (RMS) greater than 0 and less than or equal to 5 nm.

The capping layer may be formed by any one of an inkjet printing method, a transfer printing method, and a spin coating method.

It may further include at least one of forming a first charge injection layer between the first electrode and the first charge transport layer, and forming a second charge injection layer between the second electrode and the second charge transport layer.

The quantum dot light emitting layer may be formed to include a first quantum dot light emitting portion disposed to correspond to a first pixel region, a second quantum dot light emitting portion disposed to correspond to a second pixel region, and a third quantum dot light emitting portion disposed to correspond to a third pixel region; the capping layer may be formed to include a first capping layer portion disposed to correspond to the first pixel region, a second capping layer portion disposed to correspond to the second pixel region, and a third capping layer portion disposed to correspond to the third pixel region, and at least two of the first to third capping layers may have different thicknesses.

### Advantageous Effects

According to embodiments of the present invention, it is possible to implement a quantum dot light emitting device which may improve optical characteristics according to the viewing angle and at the same time, may increase efficiency due to light scattering by applying a capping layer having multifunctionality formed through a predetermined solution process. In addition, according to embodiments of the present invention, it is possible to implement a quantum dot light emitting device which is advantageous in terms of process difficulty and process cost, and may easily control the thickness and morphology of a capping layer depending on the emission wavelength by applying a capping layer formed through a solution process.

Since the auxiliary layer (capping layer) formed through the existing deposition process is mostly a homogeneous thin film, it is difficult to expect a light scattering effect inside the thin film. The changes in optical interference characteristics through adjusting the thickness of the auxiliary layer may alleviate viewing angle dependence to some extent, but it is difficult to improve external quantum efficiency (EQE).

The capping layer formed by the solution process proposed in an embodiment of the present invention exhibits a light scattering effect due to the non-homogeneous thin film characteristics, and in connection with this effect, the waveguide effect inside the capping layer is reduced and the surface plasmon loss is reduced at the upper electrode, resulting in a remarkable improvement in external quantum efficiency (EQE).

In addition, in the capping layer proposed in an embodiment of the present invention, since it is easy to control the thickness through a solution process such as an inkjet printing process and a transfer printing process, and it is quite easy to control the morphology of the thin film (capping layer) depending on the constituent materials of the solution process, type of solvent, annealing conditions, and the like, it may be easy to optimize the capping layer according to the emission wavelength and improve device characteristics.

If the technology according to the embodiments of the present invention is applied, it is possible to implement an RGB top emission QLED array with uniform light emission characteristics regardless of the viewing angle, and the related technology may be used in various optical application devices. Accordingly, it may become easier for quantum dot light emitting devices with a top emission structure to be applied to enter cutting-edge devices such as wearable displays, head-mounted displays, and AR (augmented reality)/VR (virtual reality) displays.

However, the effects of the present invention are not limited to the above effects and may be expanded in various ways without departing from the technological spirit and scope of the present invention.

### BRIEF DESCRIPTION OF THE DRAWINGS

FIG. 1 is a perspective view illustrating a quantum dot light emitting device and a manufacturing method thereof according to an embodiment of the present invention.

FIG. 2 is a diagram showing a modeling method reflecting the non-homogeneous thin film characteristics of a capping layer applied to the quantum dot light emitting device according to an embodiment of the present invention.

FIG. 3 is a TEM (transmission electron microscope) image illustrating a structure of a quantum dot which may be applied to a quantum dot light emitting device according to an embodiment of the present invention.

FIG. 4 is a perspective view showing a quantum dot light emitting device having a top emission structure according to the first comparative example.

FIG. 5 is a perspective view showing a quantum dot light emitting device having a top emission structure according to the second comparative example.

FIG. 6 is a lateral TEM image of the quantum dot light emitting device according to the first comparative example described in FIG. 4.

FIG. 7 is a lateral TEM image of the quantum dot light emitting device according to the embodiment described in FIG. 1.

FIG. 8 is an SEM (scanning electron microscope) image showing the surface of a capping layer formed through a solution process which may be applied to a quantum dot light emitting device according to an embodiment of the present invention.

FIG. 9 is a conceptual diagram showing a simulation method for light scattering occurring in the capping layer of a quantum dot light emitting device according to an embodiment of the present invention.

FIG. 10A is a graph showing the change in normalized external quantum efficiency (EQE) according to the capping layer (CPL) thickness of the quantum dot light emitting device according to an embodiment of the present invention and a comparative example.

FIG. 10B is a graph showing the results of evaluating the emission intensity characteristics according to the viewing angle of quantum dot light emitting devices according to an embodiment of the present invention and a comparative example.

FIG. 11 is a graph showing the results of evaluating the haze characteristics of quantum dot light emitting devices according to an embodiment of the present invention and a comparative example.

FIG. 12 shows the results evaluating the change in normalized scattering intensity according to the distribution factor of the capping layer (s-CPL) which may be applied to the quantum dot light emitting device according to an embodiment of the present invention.

FIG. 13 is a graph showing the change in EQE characteristics according to a thickness of the capping layer (CPL) of a quantum dot light emitting device with an RGB top emission structure.

FIG. 14 is a graph showing the results evaluating the viewing angle-emission intensity characteristics according to a thickness of the capping layer (CPL) of a quantum dot light emitting device with an RGB top emission structure.

FIG. 15 is a graph showing the results evaluating the viewing angle-emission spectrum characteristics according to a thickness of the capping layer (CPL) of a quantum dot light emitting device with an RGB top emission structure.

FIG. 16 is a graph showing the results evaluating the viewing angle-emission spectrum characteristics according to a thickness of the capping layer (s-CPL) of a blue quantum dot light emitting device with a top emission structure obtained through an optimization experiment, according to an embodiment of the present invention.

FIG. 17 is a graph showing changes in the peak wavelength (λₘₐₓ) and full width at half maximum (FWHM) according to the viewing angle depending on the thickness of the capping layer (s-CPL) of a blue quantum dot light emitting device with a top emission structure obtained through an optimization experiment, according to an embodiment of the present invention.

FIG. 18 is a cross-sectional view for explaining a quantum dot light emitting device and a manufacturing method thereof according to another embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and material tolerances, and exact or absolute figures provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

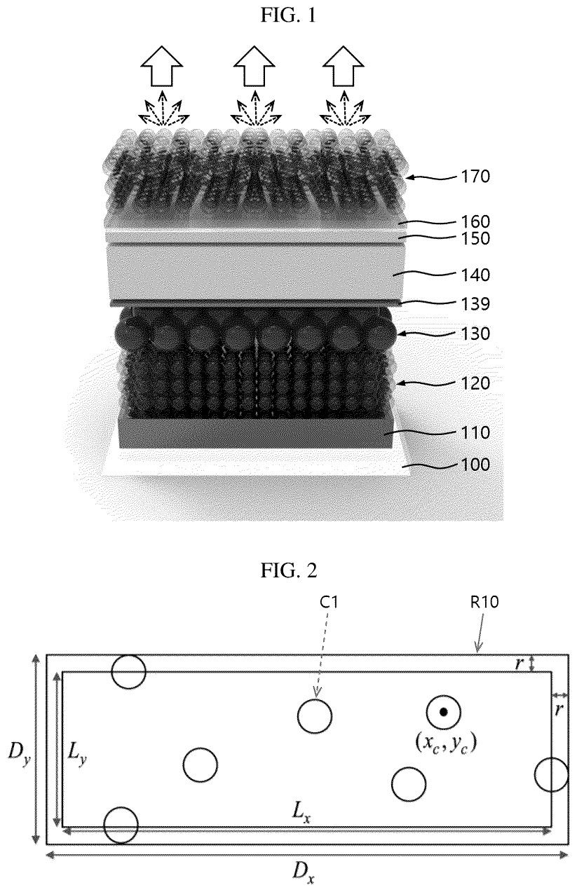

FIG. 1 is a perspective view illustrating a quantum dot light emitting device and a manufacturing method thereof according to an embodiment of the present invention.

Referring to FIG. 1, a quantum dot light emitting device according to an embodiment of the present invention may include a substrate 100. The substrate 100 may be a glass substrate, but the types of the substrate 100 may vary. For example, the substrate 100 may be a plastic substrate, a sapphire (Al₂O₃) substrate, a silicon (Si) substrate, or the like. Here, the plastic substrate may include, but is not limited to, polyethylene naphthalate (PEN), polyethylene terephthalate (PET), and the like. The specific material of the substrate 100 may vary.

The quantum dot light emitting device may include a first electrode 110 disposed on the substrate 100, a second electrode 160 disposed on the substrate 100 and spaced apart from the first electrode 110 in a direction perpendicular to the substrate 100, and a quantum dot light emitting layer 130 disposed between the first electrode 110 and the second electrode 160. In addition, the quantum dot light emitting device may include a first charge transport layer disposed between the first electrode 110 and the quantum dot light emitting layer 130 and a second charge transport layer disposed between the second electrode 160 and the quantum dot light emitting layer 130. In this embodiment, the first charge transport layer may be an electron transport layer (ETL) 120, and the second charge transport layer may be a hole transport layer (HTL) 140. In addition, the quantum dot light emitting device may further include at least one of a first charge injection layer disposed between the first electrode 110 and the first charge transport layer (i.e., 120), and a second charge injection layer disposed between the second electrode 160 and the second charge transport layer (i.e., 140). In this embodiment, the second charge injection layer may be a hole injection layer (HIL) 150. The first charge injection layer may be an electron injection layer (EIL), but this may not be applied in this embodiment. The positions of the first charge transport layer and the second charge transport layer may be reversed. Additionally, as the positions of the first charge transport layer and the second charge transport layer change, the position of at least one of the first charge injection layer and the second charge injection layer may also change.

The quantum dot light emitting device may include a structure in which the first electrode 110, the electron transport layer 120, the quantum dot light emitting layer 130, the hole transport layer 140, the hole injection layer 150, and the second electrode 160 which are sequentially stacked on the upper surface of the substrate 100. In the quantum dot light emitting device, the stack structure existing between the first electrode 110 and the second electrode 160 may be reversed in the vertical direction.

The quantum dot light emitting device may include a capping layer 170 disposed on the second electrode 160 and formed through a solution process. The capping layer 170 may play a role in controlling microcavity interference and may also have the characteristic of a light scattering layer. Here, the microcavity interference may mean microcavity interference within the quantum dot light emitting device, that is, microcavity interference between the first electrode 110 and the second electrode 160. The capping layer 170 is disposed on the second electrode 160 and serves to control the microcavity interference, thereby improving light extraction characteristics due to constructive interference and serving to alleviate viewing angle dependence. Additionally, the capping layer 170 may have a light scattering effect on the light generated from the quantum dot light emitting layer 130. In other words, the capping layer 170 may also serve as a light scattering layer. Accordingly, the capping layer 170 may serve to improve luminance and viewing angle characteristics by increasing light extraction efficiency through a light scattering effect. As the capping layer 170 may tune microcavity interference and also serve as a light scattering layer, it may be said to have multifunctionality in this respect.

The quantum dot light emitting device may have a top emission structure which emits light from the quantum dot light emitting layer 130 toward the side where the second electrode 160 is disposed, that is, opposite to the side where the substrate 100 is disposed (i.e., toward the front-surface of the device). In other words, the quantum dot light emitting device may have a top emission structure which emits light from the quantum dot light emitting layer 130 toward a direction where the capping layer 170 is disposed.

The first electrode 110 may be a reflective electrode, and the second electrode 160 may be a transparent electrode (a light-transmissive electrode). Both of the first electrode 110 and the second electrode 160 may be formed of a metal or a metallic material to generate an optical microcavity effect. In addition, the gap between the first electrode 110 and the second electrode 160, the gap between the first electrode 110 and the quantum dot light emitting layer 130, and the gap between the quantum dot light emitting layer 130 and the second electrode 160 may be controlled to generate optical constructive interference associated with the emission of light. The light emitted from the quantum dot light emitting layer 130 to the front of the device, and the light generated from the quantum dot light emitting layer 130, reflected by the first electrode 110, and then emitted to the front of the device may have a strengthening effect caused by resonance due to the microcavity structure.

The first electrode 110 may include a first metal layer having a first thickness, and the second electrode 160 may include a second metal layer having a second thickness smaller than the first thickness. As a specific example, a Ag layer (silver layer) having a thickness of about 80 nm or more or about 85 nm or more may be deposited and used as the first electrode 110 for high reflectance, and as the second electrode 160, a Ag layer (silver layer) having a thickness of about 30 nm or less or about 25 nm or less may be deposited and used for high transmittance. The thickness of the first electrode 110 may be approximately 80 to 120 nm, and the thickness of the second electrode 160 may be approximately 8 to 30 nm. The materials of the first electrode 110 and the second electrode 160 are not limited to Ag and may vary in various ways.

The quantum dot emission layer 130 may include quantum dots. The quantum dot may have a core-shell structure including a core portion and a shell portion, but may not have a core-shell structure. When the quantum dot has a core-shell structure, the shell portion may have a single shell or may have a plurality of shell layers. Depending on the material, composition, size, etc. of the quantum dots, the emission wavelength may vary. The quantum dot light emitting layer 130 may be formed through a solution process such as an inkjet printing method or a spin coating method. The thickness of the quantum dot light emitting layer 130 may be approximately 10 to 60 nm as a non-limiting example.

The electron transport layer 120 may include a metal oxide-based material. For example, the electron transport layer 120 may include a zinc oxide (ZnO)-based material or a titanium oxide-based material. The zinc oxide (ZnO)-based material may include zinc oxide (ZnO) or a material doped with a metal into zinc oxide (ZnO), and the material doped with a metal into zinc oxide (ZnO) may be, for example, ZnMgO, ZnAlO, and the like. The titanium oxide-based material may include, for example, TiO₂. Additionally, the metal oxide-based material included in the electron transport layer 120 may have a nanoparticle shape. As a specific example, the electron transport layer 120 may include zinc oxide (ZnO)-based nanoparticles. Here, the zinc oxide (ZnO)-based nanoparticles may be ZnO nanoparticles. The thickness of the electron transport layer 120 may be approximately 10 to 200 nm as a non-limiting example.

The hole transport layer 140 and the hole injection layer 150 may include a material which has high hole mobility or lowers a hole injection barrier into the quantum dots. The hole transport layer 140 may include a predetermined organic material. As a non-limiting example, the hole transport layer 140 may include TCTA [tris(4-carbazoyl-9-ylphenyl)amine]. The specific material of the hole transport layer 140 may vary. The thickness of the hole transport layer 140 may be approximately 10 to 200 nm as a non-limiting example.

The hole injection layer 150 may include at least one of, for example, MoO₃, V₂O₅, WO₃, HAT-CN, CuPc, PEDOT:PSS, etc. Here, HAT-CN is hexaazatriphenylene hexacarbonitrile, CuPc is copper phthalocyanine, and PEDOT:PSS is poly(ethylenedioxythiophene):polystyrene sulphonate. As a non-limiting example, the hole injection layer 150 may be a MoO₃ thin film. The thickness of the hole injection layer 150 may be approximately 5 to 100 nm as a non-limiting example. The hole injection barrier may be reduced, and hole injection characteristics may be improved due to the hole injection layer 150, and, as a result, light emission characteristics and light emission efficiency may be improved.

According to one embodiment, the capping layer 170 may include a plurality of nanoparticles. In this case, the plurality of nanoparticles may form a plurality of nanoparticle clusters within the capping layer 170. The nanoparticle cluster may be an aggregate of nanoparticles. In the capping layer 170, the plurality of nanoparticle clusters may be arranged generally randomly. The plurality of nanoparticles included in the capping layer 170 may include at least one of a metal oxide and a non-metal oxide. For example, the plurality of nanoparticles may include at least one of zinc oxide (ZnO), zinc magnesium oxide (ZnMgO), zinc aluminum oxide (ZnAlO), titanium oxide (TiO₂), and silicon oxide (SiO₂). Here, the average particle diameter of the nanoparticles may be several nanometers to several tens of nanometers. As a non-limiting example, the average particle diameter of the nanoparticles may be about 1 nm to 40 nm. The thickness of the capping layer 170 may be approximately 10 to 250 nm as a non-limiting example.

According to one embodiment, the capping layer 170 may have a distribution factor (ρ) in a range of about 0.2 to 5, where the distribution factor (ρ) may be defined by an equation ρ=N(A_{cluster}/A_{s-CPL}). In the above equation, A_{cluster} may represent an area occupied by the nanoparticle cluster in a cross-sectional region of the capping layer 170, As-CPL may represent an area occupied by the entire capping layer corresponding to the cross-sectional region, and N may represent a number of the nanoparticle cluster in the cross-sectional region. In some cases, the distribution factor (ρ) of the capping layer 170 may be greater than 5. The distribution factor (ρ) will be described in more detail later with reference to FIG. 2.

Additionally, according to one embodiment, the capping layer 170 may have a surface roughness greater than 0 and less than or equal to 5 nm. For example, the capping layer 170 may have a surface roughness of greater than or equal to about 2 nm and less than or equal to about 5 nm. Here, the surface roughness may be RMS (root-mean-square) surface roughness. Because the plurality of nanoparticle clusters described above may be randomly arranged within the capping layer 170, the capping layer 170 may have a relatively large surface roughness.

The capping layer 170 may have non-homogeneous thin film characteristics. In this regard, the capping layer 170 may exhibit excellent light scattering characteristics. In connection with light emitted from the quantum dot light emitting device according to the embodiment, the capping layer 170 may have a scattering intensity of, for example, about 10 to 50%. In other words, the capping layer 170 may have a normalized scattering intensity in a range of about 1.1 to 1.5. However, in some cases, the normalized scattering intensity of the capping layer 170 may be greater than 1.5. Here, the normalization may be normalization set to 1 in the case where there is no capping layer.

Additionally, the quantum dot light emitting device according to an embodiment of the present invention may further include an insertion layer 139 disposed between the quantum dot light emitting layer 130 and the hole transport layer 140. The insertion layer 139 may serve to optimize charge balance. As a non-limiting example, the insertion layer 139 may be formed of CzSi [9-(4-tert-butylphenyl)-3,6-bis(triphenylsilyl)-9H-carbazole], and may be formed to have a thickness of several nm (for example, about 3 nm). However, application of the insertion layer 139 may be optional.

A manufacturing method of a quantum dot light emitting device according to an embodiment of the present invention will be described illustratively as follows.

The manufacturing method of the quantum dot light emitting device may include preparing a substrate 100. The substrate 100 may be a glass substrate, but the types of the substrate 100 may vary. For example, the substrate 100 may be a plastic substrate, sapphire substrate, silicon substrate, and the like. The substrate 100 may be washed with acetone, isopropyl alcohol (IPA), and distilled water in that order, and then dried at a temperature of about 120° C. However, these washing and drying conditions are merely examples and may vary.

The method of manufacturing the quantum dot light emitting device may include forming a first electrode 110 on the substrate 100. The first electrode 110 may be formed of a metal or a metallic material through a deposition process.

Next, a first charge transport layer may be formed on the first electrode 110. Here, the first charge transport layer may be an electron transport layer 120. The electron transport layer 120 may include a metal oxide-based material. For example, the electron transport layer 120 may include a zinc oxide (ZnO)-based material or a titanium oxide-based material. The zinc oxide (ZnO)-based material may include zinc oxide (ZnO) or a material in which a metal is doped into zinc oxide (ZnO), and the material in which a metal is doped into zinc oxide (ZnO) may be, for example, ZnMgO, ZnAlO, etc. The titanium oxide-based material may include, for example, TiO₂. Additionally, the metal oxide-based material included in the electron transport layer 120 may have a nanoparticle form. As a specific example, the electron transport layer 120 may include zinc oxide (ZnO)-based nanoparticles. Here, the zinc oxide (ZnO)-based nanoparticles may be ZnO nanoparticles. In this case, a solution (nanoparticle solution) containing ZnO nanoparticles may be applied on the first electrode 110 by spin coating, and then heat-treated in a nitrogen atmosphere at a temperature of about 100° C. for about 30 minutes, so that the electron transport layer 120 may be formed.

A quantum dot light emitting layer 130 including quantum dots may be formed on the first electron transport layer 120. The quantum dot light emitting layer 130 may be formed, for example, by a spin coating method or an inkjet printing method using a solution process. A second charge transport layer may be formed on the quantum dot light emitting layer 130. The second charge transport layer may be a hole transport layer 140. The hole transport layer 140 may be formed through a deposition process. As a non-limiting example, the hole transport layer 140 may be formed of TCTA [4,4′,4″-Tris(carbazol-9-yl)triphenylamine].

Next, a hole injection layer 150 and a second electrode 160 may be sequentially formed on the hole transport layer 140 through a deposition process. The hole injection layer 150 may be formed to include at least one of, for example, MoO₃, V₂O₅, WO₃, HAT-CN, CuPc, PEDOT: PSS, and the like. As a non-limiting example, the hole injection layer 150 may be a MoO₃, thin film. The second electrode 160 may be formed of a metal or by a metallic material. The second electrode 160 may have a thickness smaller than that of the first electrode 110.

A capping layer 170 may be formed on the second electrode 160 by using a solution process. The capping layer 170 may include a plurality of nanoparticles, and the plurality of nanoparticles may constitute a plurality of nanoparticle clusters. The plurality of nanoparticles may include at least one of a metal oxide and a non-metal oxide. For example, the plurality of nanoparticles may include at least one of zinc oxide (ZnO), zinc magnesium oxide (ZnMgO), zinc aluminum oxide (ZnAlO), titanium oxide (TiO₂), and silicon oxide (SiO₂). The capping layer 170 may be formed by using one of an inkjet printing method, a transfer printing method, and a spin coating method.

Additionally, the manufacturing method of the quantum dot light emitting device may further include forming an insertion layer 139 between the quantum dot light emitting layer 130 and the hole transport layer 140. The insertion layer 139 may serve to optimize charge balance. However, formation of the insertion layer 139 may be optional.

In addition, the method of manufacturing the quantum dot light emitting device may further include forming an electron injection layer between the first electrode 110 and the electron transport layer 120. The electron injection layer may be referred to as a first charge injection layer. The hole injection layer 150 may be referred to as a second charge injection layer. At least one of the first charge injection layer and the second charge injection layer may be further formed.

FIG. 2 is a diagram showing a modeling method reflecting the non-homogeneous thin film characteristics of a capping layer applied to the quantum dot light emitting device according to an embodiment of the present invention.

Referring to FIG. 2, the capping layer of the quantum dot light emitting device according to an embodiment of the present invention, that is, the capping layer (s-CPL) formed through a solution process, may include a plurality of nanoparticles, and the plurality of nanoparticles may constitute a plurality of nanoparticle clusters C1 within the capping layer. The nanoparticle cluster C1 may be an aggregate of nanoparticles. A plurality of nanoparticle clusters C1 may be arranged generally randomly within the capping layer.

The density of nanoparticle clusters C1 within the capping layer may be defined as a distribution factor (ρ). The distribution factor (ρ) may be expressed by the equation ρ=N(A_{cluster}/A_{s-CPL}). In the above equation, A_{cluster} represents an area occupied by the nanoparticle cluster C1 in a cross-sectional region R10 of the capping layer, A_{s-CPL} represents an area occupied by the entire capping layer corresponding to the cross-sectional region R10, and N represents the number of nanoparticle cluster C1 in the cross-sectional region R10. As-CPL may be an area of the cross-sectional region R10. In other words, the cross-sectional region R10 may be a projected region of the entire capping layer corresponding thereto. A_{cluster} may be the area occupied by the nanoparticle cluster C1 in a predetermined two-dimensional region, A_{s-CPL} may be the area of the entire two-dimensional region, and N may be the number of nanoparticle cluster C1 in the two-dimensional region. Here, the two-dimensional region may correspond to the cross-sectional region R10. As the proportion of A_{cluster} in A_{s-CPL} increases, and as N increases, the distribution factor (ρ) may increase.

In an embodiment of the present invention, the distribution factor (ρ) of the capping layer may be about 0.2 to 5. When this condition is satisfied, the light scattering characteristics of the capping layer may be further improved. However, in some cases, the distribution factor (ρ) of the capping layer may be greater than 5. The distribution factor (ρ) may also be referred to as a filling factor.

In order to reflect the non-homogeneous characteristics of the capping layer (s-CPL) formed by the solution process, a two-dimensional simulation was conducted through a modeling in which circles (corresponding to nanoparticle clusters) with a diameter of 10 nm (radius r=5 nm) are randomly distributed as shown in FIG. 2. At this time, the refractive index of the nanoparticle cluster C1 was assumed to be 1.8, and the remaining space was assumed to be air and its refractive index was assumed to be 1. The distribution factor (ρ) may be evaluated by repeating the simulation several times and calculating the average value.

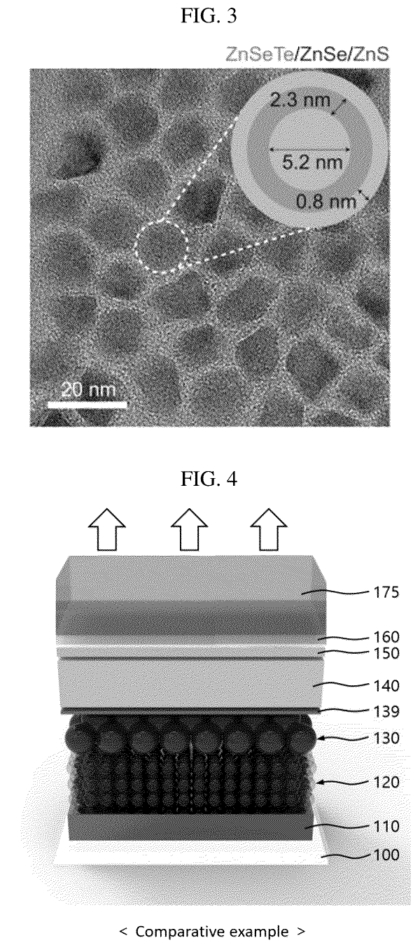

FIG. 3 is a TEM (transmission electron microscope) image illustrating a structure of a quantum dot which may be applied to a quantum dot light emitting device according to an embodiment of the present invention.

Referring to FIG. 3, quantum dots for blue light emission are illustrated. Quantum dots may have a core-shell structure having a core portion and a shell portion surrounding it. The shell portion may include a plurality of shell layers. For example, the quantum dot may have a ZnSeTe/ZnSe/ZnS structure. The core portion may include ZnSeTe, and the shell portion may include ZnSe and ZnS. However, this configuration of quantum dots is merely an example, and the configuration of a quantum dot may vary depending on the emission wavelength and required characteristics.

FIG. 4 is a perspective view showing a quantum dot light emitting device having a top emission structure according to the first comparative example.

Referring to FIG. 4, the quantum dot light emitting device according to the first comparative example may include a capping layer 175 formed through a deposition process. In this specification, the capping layer 175 formed through a deposition process may be referred to as e-CPL. The capping layer 175 may be formed by depositing organic materials such as TAPC, TCTA, CBP, and NPB, or MoO₃. TAPC is 1,1-bis[(di-4-tolylamino)phenyl]cyclohexane, TCTA is tris(4-carbazoyl-9-ylphenyl)amine, and CBP is 4,4′-Bis(N-carbazolyl)-1,1′-biphenyl, and NPB is N,N′-di(1-naphthyl)-N,N′-diphenyl benzidine. In this comparative example, the capping layer 175 was formed of TAPC. The capping layer 175 formed through a deposition process may have homogeneous thin film characteristics. Accordingly, the capping layer 175 may not have light scattering characteristics. In the quantum dot light emitting device according to the first comparative example, the remaining structure except for the structure of the capping layer 175 may be the same as the structure of the embodiment described with reference to FIG. 1.

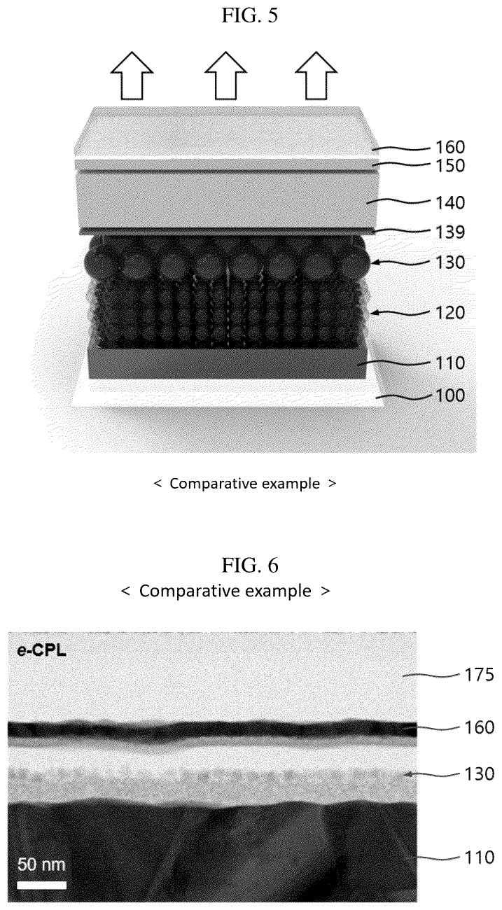

FIG. 5 is a perspective view showing a quantum dot light emitting device having a top emission structure according to the second comparative example.

Referring to FIG. 5, the quantum dot light emitting device according to the second comparative example may have a structure in which a capping layer is not formed on the second electrode 160. The remaining structure except for the fact that the capping layer is not formed may be the same as the structure of the embodiment described with reference to FIG. 1.

FIG. 6 is a lateral TEM image of the quantum dot light emitting device according to the first comparative example described in FIG. 4. In FIG. 6, the reference numbers of major layers are indicated, and the overall layer structure may be the same as that described in FIG. 4.

Referring to FIG. 6, the quantum dot light emitting device according to the first comparative example includes a capping layer 175 formed through a deposition process, that is, e-CPL. The e-CPL may have homogeneous thin film properties.

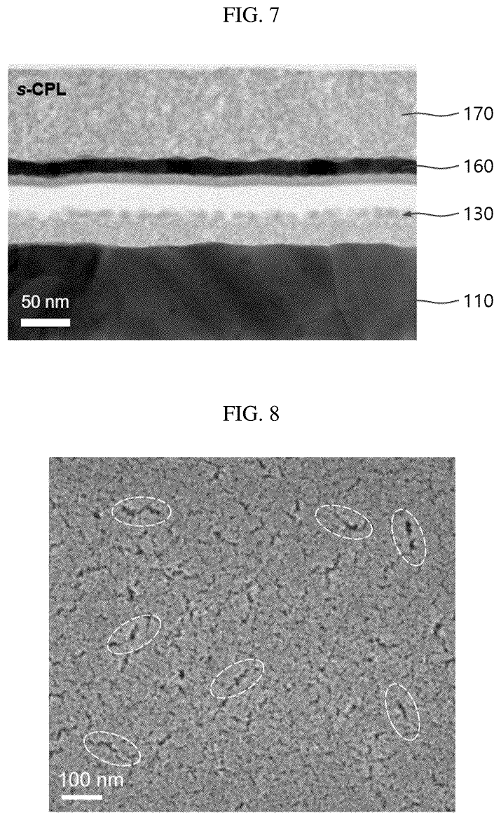

FIG. 7 is a lateral TEM image of the quantum dot light emitting device according to the embodiment described in FIG. 1. In FIG. 7, the reference numbers of major layers are indicated, and the overall layer structure may be the same as that described in FIG. 1.

Referring to FIG. 7, a quantum dot light emitting device according to an embodiment of the present invention may include a capping layer 170 formed through a solution process, that is, s-CPL. The s-CPL may include a plurality of nanoparticles and may have non-homogeneous thin film properties.

FIG. 8 is an SEM (scanning electron microscope) image showing the surface of a capping layer formed through a solution process which may be applied to a quantum dot light emitting device according to an embodiment of the present invention. At this time, the thickness of the capping layer may be 80 nm.

Referring to FIG. 8, the capping layer formed through a solution process, that is, s-CPL, may include surface cracks naturally formed during the formation process. The dotted oval indicates the portion where the surface crack is formed.

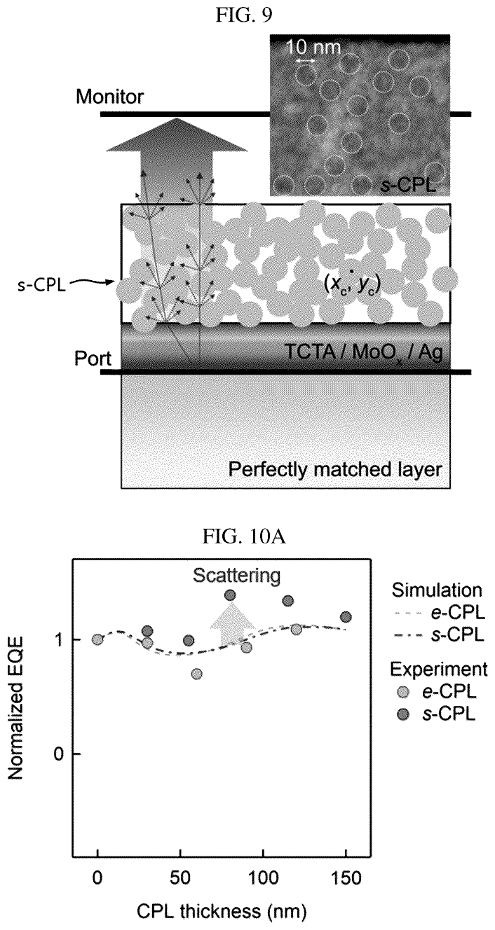

FIG. 9 is a conceptual diagram showing a simulation method for light scattering occurring in the capping layer of a quantum dot light emitting device according to an embodiment of the present invention.

Referring to FIG. 9, monochromatic waves (λ=455 nm) may be emitted from a port and pass through the s-CPL, where nanoparticle clusters are randomly arranged, so that the intensity of light may be measured on the monitor. Here, the port may correspond to a quantum dot light emitting layer. The TCTA/MoOx/Ag stack may correspond to the hole transport layer/hole injection layer/second electrode. The s-CPL may be, for example, a ZnO nanocluster layer. Light may be scattered and emitted from s-CPL. The cross-sectional TEM image of s-CPL included in FIG. 9 illustrates the diameter of each cluster.

The device characteristics evaluation and the simulation methods for quantum dot light emitting devices according to the embodiments and the comparative examples are described as follows. The current characteristics of the quantum dot light emitting device were obtained by applying voltage through a Keithley 2400 source meter, and the intensity of light was measured by using a Keithley 2000 multimeter and a silicon photodiode. The luminescence spectrum according to the viewing angle was obtained using a rotating stage and Minolta CS 2000, and efficiency and luminance were calculated through current-voltage characteristics, light intensity, and luminescence spectrum. For optical simulation, COMSOL Multiphysics which takes into account the inhomogeneity and light scattering characteristics of s-CPL was used along with setFos which assumes all thin films to be homogeneous thin films.

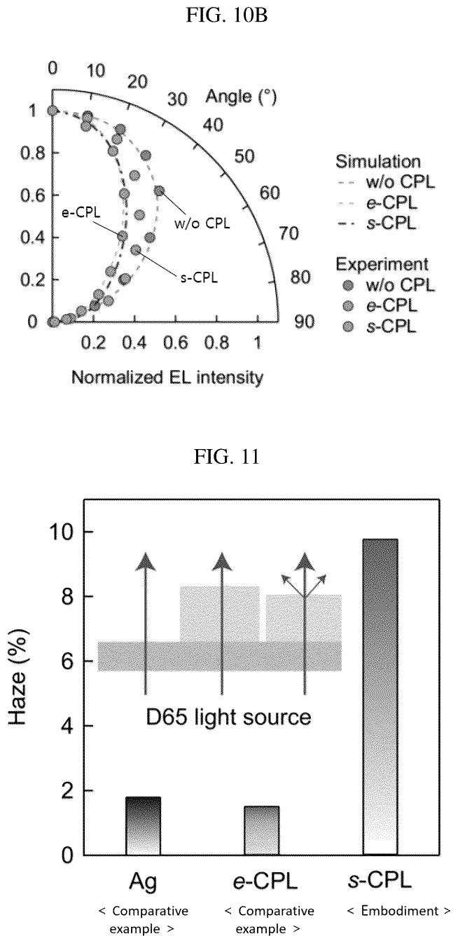

FIG. 10A is a graph showing the change in normalized external quantum efficiency (EQE) according to the capping layer (CPL) thickness of the quantum dot light emitting device according to an embodiment of the present invention and a comparative example. FIG. 10A includes setFos simulation results (dotted lines) assuming a homogeneous thin film and actual experimental results (circular marks). The above embodiment applies s-CPL and has the structure shown in FIG. 1, and the comparative example applies e-CPL and has the structure shown in FIG. 4.

Referring to FIG. 10A, it may be confirmed that the quantum dot light emitting device according to the embodiment to which s-CPL is applied has a much more remarkably improved EQE than the quantum dot light emitting device according to the comparative example to which e-CPL is applied. This may be due to the light scattering effect of s-CPL. In addition, it may be seen that e-CPL is close to a homogeneous thin film, while s-CPL is a non-homogeneous thin film through comparison of setFos simulation results (dotted line) which assuming a homogeneous thin film and actual experimental results (circular marks).

FIG. 10B is a graph showing the results of evaluating the emission intensity characteristics according to the viewing angle of quantum dot light emitting devices according to an embodiment of the present invention and a comparative example. FIG. 10B includes setFos simulation results (dotted lines) assuming a homogeneous thin film and actual experimental results (circular marks). The embodiment applies s-CPL and has the structure of FIG. 1, the first comparative example applies e-CPL and has the structure of FIG. 4, and the second comparative example does not apply a capping layer (w/o CPL) and has the structure of FIG. 5.

Referring to FIG. 10B, it can be seen that the quantum dot light emitting device according to the embodiment to which s-CPL is applied exhibits improved viewing angle characteristics than the quantum dot light emitting device according to the comparative example to which e-CPL is applied. Additionally, through comparison of setFos simulation results (dotted line) assuming a homogeneous thin film and actual experimental results (circular marks), it can be seen that e-CPL is close to a homogeneous thin film, while s-CPL is a non-homogeneous thin film. The s-CPL applied in the embodiment may have a light scattering function.

FIG. 11 is a graph showing the results of evaluating the haze characteristics of quantum dot light emitting devices according to an embodiment of the present invention and a comparative example. FIG. 11 shows the haze characteristics of each Ag layer, Ag/e-CPL layer, and Ag/s-CPL layer. Here, the Ag layer may correspond to the structure applied to the comparative example of FIG. 5, the Ag/e-CPL layer may correspond to the structure applied to the comparative example of FIG. 4, and the Ag/s-CPL layer may correspond to the structure applied to the embodiment of FIG. 1. The inset of FIG. 11 shows a simplified view of the light propagation process.

Referring to FIG. 11, it may be confirmed that the quantum dot light emitting device according to the embodiment exhibits a much higher haze value than the quantum dot light emitting devices according to the comparative examples. This may be due to the light scattering characteristics of s-CPL. In other words, s-CPL applied to the quantum dot light emitting device according to the embodiment may have excellent light scattering characteristics.

For example, a quantum dot light emitting device according to an embodiment of the present invention may have a haze of about 5 to 20%. If the haze becomes too large, the clarity of the display may deteriorate. In particular, when performing high-resolution patterning, if the Haze % becomes too large, color mixing between pixels may occur. The haze intensity of the quantum dot light emitting device according to an embodiment of the present invention may correspond to an intensity which may improve light extraction of the device without causing pixel crosstalk. The haze of the anti-glare film used in existing displays may be about 20 to 70% depending on the display's application field. However, as display fields which require high resolution, such as augmented reality (AR)/virtual reality (VR) fields, slightly lower haze may be required than before.

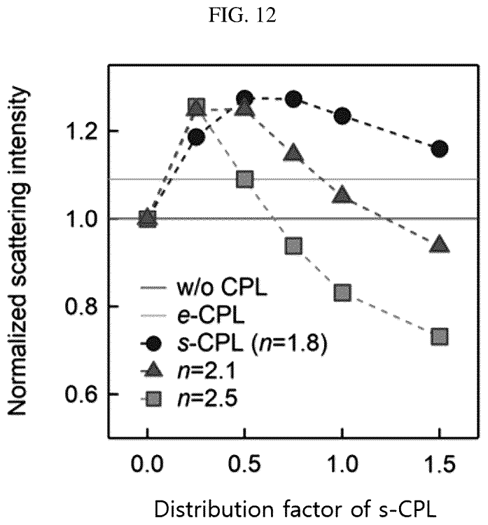

FIG. 12 shows the results evaluating the change in normalized scattering intensity according to the distribution factor of the capping layer (s-CPL) which may be applied to the quantum dot light emitting device according to an embodiment of the present invention. The change in light scattering characteristics according to changes in the refractive index (n) of nanoparticles included in the capping layer (s-CPL) were also evaluated. FIG. 12 shows the results obtained through COMSOL simulation. For comparison, FIG. 12 also includes results for the case without a capping layer (i.e., w/o CPL) and a case where a capping layer (e-CPL) formed by a deposition process was applied.

Referring to FIG. 12, it may be confirmed that the capping layer (s-CPL) which may be applied to the quantum dot light emitting device according to an embodiment of the present invention exhibits a higher light scattering intensity as compared to the e-CPL within a range where predetermined conditions are satisfied. Light scattering characteristics may change depending on the distribution factor due to the density and degree of aggregation of the nanoparticles included in the capping layer (s-CPL). Additionally, light scattering characteristics may change depending on the refractive index of the nanoparticles applied to the capping layer (s-CPL).

In the case of the capping layer (s-CPL) formed through a solution process, as it is quite easy to control the morphology of the thin film (capping layer) depending on the constituent materials, solvent type, annealing conditions, and so on of the solution process, it may be quite advantageous for improving characteristics and increasing efficiency of a device. In other words, the size of nanoparticles, as the degree of aggregation between nanoparticles, and the surface roughness of the thin film (capping layer) may be relatively freely changed depending on the constituent materials of the solution process, type of solvent, annealing conditions, and the like, this may be advantageous in some respects such as improvement of characteristics and increasing efficiency of a device. In the case of the annealing, as a non-limiting example, temperature conditions may be adjusted within the range of about 50° C. to 150° C. As a non-limiting example, in the case of the solvent, it is possible to select from alcohol-based solvents such as butanol, ethanol, and methanol, and use the selected solvent. In addition, the specific conditions of the solution process may vary.

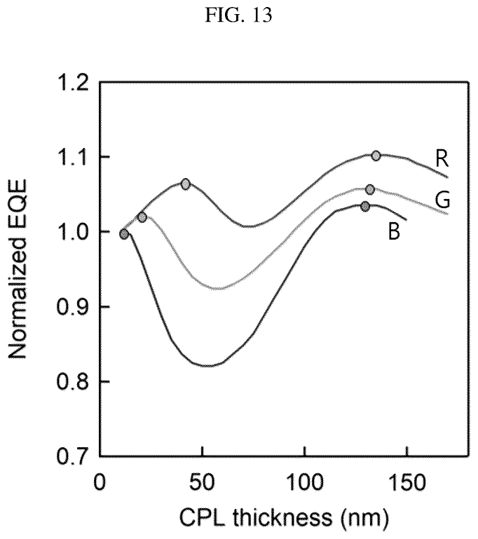

FIG. 13 is a graph showing the change in EQE characteristics according to a thickness of the capping layer (CPL) of a quantum dot light emitting device with an RGB top emission structure. FIG. 13 is obtained through setFos simulation.

Referring to FIG. 13, the quantum dot light emitting device may have different optimal thicknesses of the capping layer (CPL) depending on the emission wavelength (R/G/B). The solution process may be an easier patterning process than the deposition process. Therefore, if a solution process is applied, it may be easy to control the thickness of the capping layer according to the emission wavelength. In this respect, forming a capping layer by a solution process may be advantageous for process simplification, cost reduction, and optimization of device characteristics.

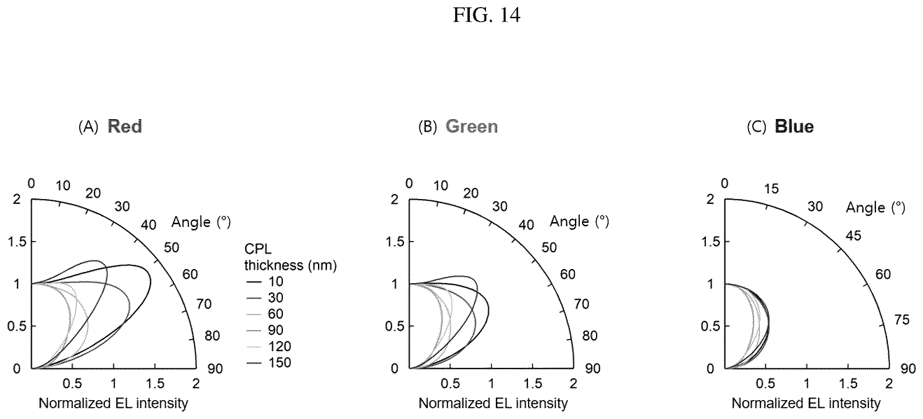

FIG. 14 is a graph showing the results evaluating the viewing angle-emission intensity characteristics according to a thickness of the capping layer (CPL) of a quantum dot light emitting device with an RGB top emission structure. FIG. 14 is obtained through setFos simulation. The graph (A) in FIG. 14 is for a red quantum dot light emitting device, the graph (B) is for a green quantum dot light emitting device, and the graph (C) is for a blue quantum dot light emitting device.

Referring to FIG. 14, it may be confirmed that the emission intensity characteristics of the quantum dot light emitting device change depending on the viewing angle depending on the thickness of the capping layer (CPL). If the characteristic curve is close to the Lambertian distribution, it may be said to have excellent viewing angle characteristics. Additionally, in terms of viewing angle characteristics, the quantum dot light emitting device may have different optimal thicknesses of the capping layer (CPL) depending on the emission wavelength (R/G/B).

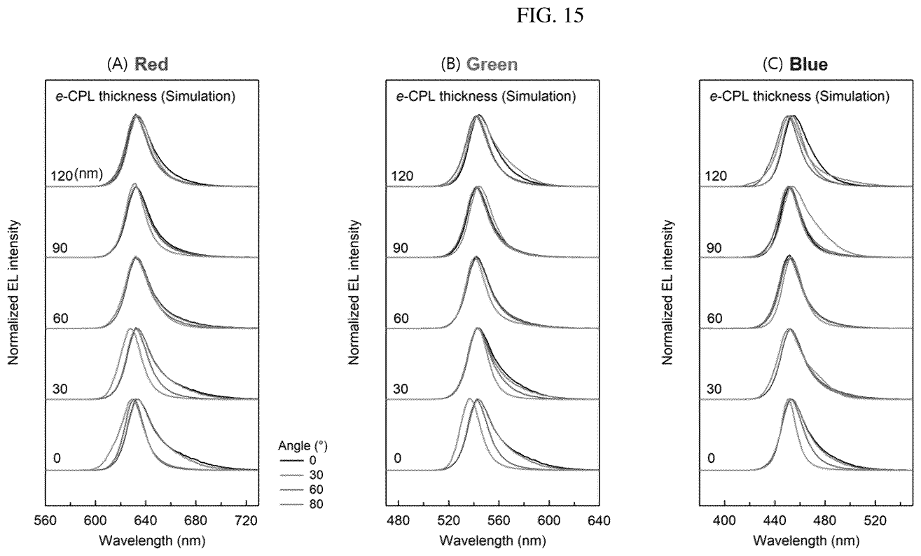

FIG. 15 is a graph showing the results evaluating the viewing angle-emission spectrum characteristics according to a thickness of the capping layer (CPL) of a quantum dot light emitting device with an RGB top emission structure. FIG. 15 is obtained through setFos simulation. The graph (A) in FIG. 15 is for a red quantum dot light emitting device, the graph (B) is for a green quantum dot light emitting device, and the graph (C) is for a blue quantum dot light emitting device.

Referring to FIG. 15, it may be confirmed that the emission spectrum characteristics of the quantum dot light emitting device change according to the viewing angle depending on the thickness of the capping layer (CPL). If there is little change in the emission spectrum due to changes in viewing angle, it may be said to have excellent viewing angle characteristics. The quantum dot light emitting devices may have different optimal thickness of a capping layer (CPL) depending on the emission wavelength (R/G/B).

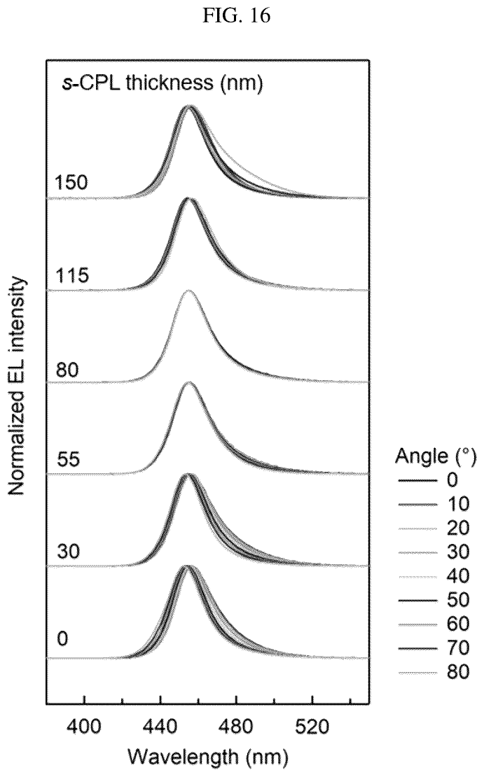

FIG. 16 is a graph showing the results evaluating the viewing angle-emission spectrum characteristics according to a thickness of the capping layer (s-CPL) of a blue quantum dot light emitting device with a top emission structure obtained through an optimization experiment, according to an embodiment of the present invention.

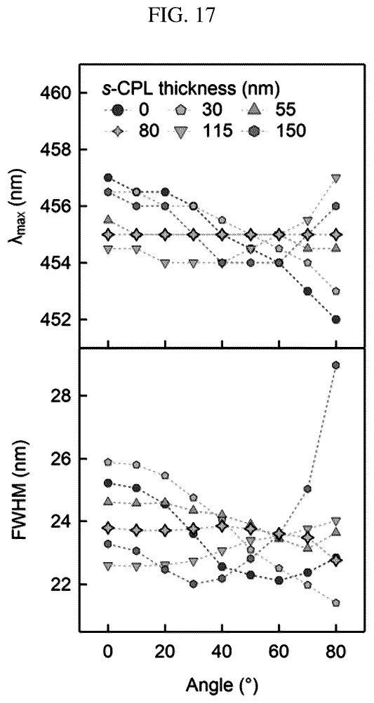

FIG. 17 is a graph showing changes in the peak wavelength (λₘₐₓ) and full width at half maximum (FWHM) according to the viewing angle depending on the thickness of the capping layer (s-CPL) of a blue quantum dot light emitting device with a top emission structure obtained through an optimization experiment, according to an embodiment of the present invention. FIG. 17 is obtained from FIG. 16.

Referring to FIGS. 16 and 17, the changes in the emission spectrum and emission intensity according to the viewing angle may be adjusted by optimizing the thickness of the capping layer (s-CPL). In the case of this embodiment, when the capping layer (s-CPL) has a thickness of about 80 nm, viewing angle characteristics may be optimized. However, the optimal thickness of the capping layer (s-CPL) may vary depending on various conditions.

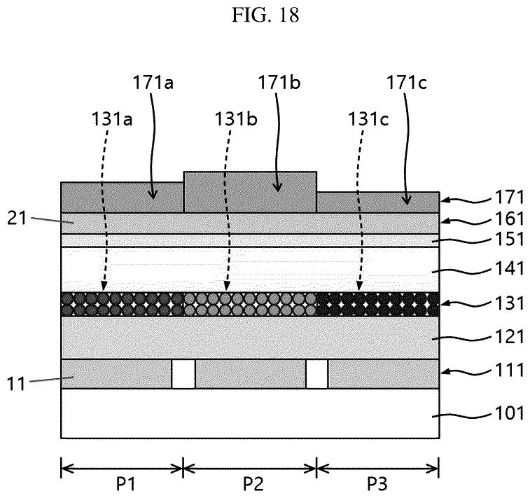

FIG. 18 is a cross-sectional view for explaining a quantum dot light emitting device and a manufacturing method thereof according to another embodiment of the present invention.

Referring to FIG. 18, the quantum dot light emitting device according to an embodiment of the present invention may include a first pixel region P1, a second pixel region P2, and a third pixel region P3 which generate light of different colors. Each pixel region (P1, P2, P3) may also be referred to as a sub-pixel region. The first pixel region P1 may be a red pixel region, the second pixel region P2 may be a green pixel region, and the third pixel region P3 may be a blue pixel region. The following description of FIG. 18 is based on the case where the first pixel region P1 is a red pixel region, the second pixel region P2 is a green pixel region, and the third pixel region P3 is a blue pixel region.

The quantum dot light emitting device according to this embodiment may include a first electrode member 111 and a second electrode member 161 which are spaced apart from each other, and may include a stack structure which is disposed between the first electrode member 111 and the second electrode member 161, and converts electrical energy supplied through the electrode members 111 and 161 into optical energy.

The first electrode member 111 may be provided on a substrate 101, a stack structure may be provided on the first electrode member 111, and the second electrode member 161 may be provided on the stack structure. The first electrode member 111 may include a plurality of first electrode elements 11. For example, the plurality of first electrode elements 11 may be arranged side by side while extending in a first direction. The plurality of first electrode elements 11 may be arranged to correspond to the plurality of pixel regions P1, P2, and P3, respectively. The second electrode member 161 may include a plurality of second electrode elements 21. For example, the plurality of second electrode elements 21 may be arranged side by side while extending in a second direction. Here, the second direction may be perpendicular to the first direction. Accordingly, the plurality of second electrode elements 21 may intersect perpendicularly with respect to the plurality of first electrode elements 11. However, the arrangement direction of the plurality of second electrode elements 21 may vary. For example, the plurality of second electrode elements 21 may extend in the same direction as the plurality of first electrode elements 11.

A quantum dot light emitting layer 131 may be disposed between the first electrode member 111 and the second electrode member 161. The quantum dot light emitting layer 131 may include a first quantum dot light emitting portion 131a disposed to correspond to the first pixel region P1, a second quantum dot light emitting portion 131b disposed to correspond to the second pixel region P2, and a third quantum dot light emitting portion 131c disposed to correspond to the pixel region P3. The first quantum dot light emitting portion 131a may contain a first quantum dot for emitting light of a first color (i.e., red). The second quantum dot light emitting portion 131b may contain second quantum dots for emitting light of a second color (i.e., green). The third quantum dot light emitting portion 131c may contain a third quantum dot for emitting light of a third color (i.e., blue).

An electron transport layer 121 may be disposed between the first electrode member 111 and the quantum dot light emitting layer 131, and a hole transport layer 141 may be disposed between the second electrode member 161 and the quantum dot light emitting layer 131. Additionally, a hole injection layer 151 may be further disposed between the second electrode member 161 and the hole transport layer 141.

A capping layer 171 may be disposed on the second electrode member 161. The capping layer 171 may include, for example, a first capping layer portion 171a disposed to correspond to the first pixel region P1, a second capping layer portion 171b disposed to correspond to the second pixel region P2, and a third capping layer portion 171c disposed to correspond to the third pixel region P3. Here, at least two of the first to third capping layer portions 171a, 171b, and 171c may have different thicknesses. The first to third capping layer portions 171a, 171b, and 171c may have different thicknesses. The thicknesses of the first to third capping layer parts 171a, 171b, and 171c shown in FIG. 18 are merely examples, and the optimal thickness of each capping layer part 171a, 171b, and 171c may vary.

The configuration of the quantum dot light emitting device having an RGB top-emission structure as shown in FIG. 18 may be modified in various ways as described with reference to FIG. 1. Additionally, the manufacturing method of the quantum dot light emitting device of FIG. 18 may be easily understood from the manufacturing method described with reference to FIG. 1, and the manufacturing method may also be modified in various ways.

In addition, in FIG. 18, a quantum dot light emitting device whose unit structure consists of three pixels (sub-pixels) is shown and described, but it may also be possible to configure a unit structure consisting of two pixels (sub-pixels) or four or more pixels (sub-pixels).

According to the embodiments of the present invention described above, it is possible to implement a quantum dot light emitting device which may improve optical characteristics according to the viewing angle and at the same time, may increase efficiency due to light scattering by applying a capping layer having multifunctionality formed through a predetermined solution process. In addition, according to embodiments of the present invention, it is possible to implement a quantum dot light emitting device which is advantageous in terms of process difficulty and process cost, and may easily control a thickness and morphology of the capping layer depending on the emission wavelength by applying a capping layer formed through a solution process.

Since the auxiliary layer (capping layer) formed through the existing deposition process is mostly a homogeneous thin film, it is difficult to expect a light scattering effect inside the thin film. The changes in optical interference characteristics through adjusting the thickness of the auxiliary layer may alleviate viewing angle dependence to some extent, but it is difficult to improve external quantum efficiency (EQE).

The capping layer formed by the solution process proposed in an embodiment of the present invention exhibits a light scattering effect due to the non-homogeneous thin film characteristics, and in connection with to this effect, the waveguide effect inside the capping layer is reduced and the surface plasmon loss is reduced at the upper electrode, resulting in a remarkable improvement in external quantum efficiency (EQE). In addition, in the capping layer proposed in an embodiment of the present invention, since it is easy to control the thickness through a solution process such as an inkjet printing process and a transfer printing process, and it is quite easy to control the morphology of the thin film (a capping layer) depending on the constituent materials of the solution process, type of solvent, annealing conditions, and the like, it may be easy to optimize the capping layer according to the emission wavelength and to improve the characteristics of the device. If the technology according to the embodiments of the present invention is applied, it is possible to implement an RGB front-emitting QLED array with uniform light emission characteristics regardless of the viewing angle, and the related technology may be used in various optical application devices. Accordingly, it may become easier for quantum dot light emitting devices with a top emission structure to be applied to cutting-edge devices such as wearable displays, head-mounted displays, and AR (augmented reality)/VR (virtual reality) displays.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with quantum dot light emitting devices and manufacturing methods thereof according to embodiments described with reference to FIGS. 1 to 3 and 7 to 18, various substitutions, changes, and modifications may be made without departing from the technological spirit of the present invention. As a specific example, the capping layer may be formed of a material other than a metal oxide or a non-metal oxide, for example, an organic material, or may be formed to include an organic material. Therefore, the scope of the invention should not be determined by the described embodiments, but should be determined by the technological concepts described in the claims.

### INDUSTRIAL APPLICABILITY

The embodiments of the present invention may be applied to optical devices and manufacturing methods thereof.

1. A quantum dot light emitting device comprising:
a first electrode;
a second electrode disposed spaced apart from the first electrode;
a quantum dot light emitting layer disposed between the first electrode and the second electrode and including quantum dots;
a first charge transport layer disposed between the first electrode and the quantum dot light emitting layer;
a second charge transport layer disposed between the second electrode and the quantum dot light emitting layer; and
a capping layer which is disposed on the second electrode, is formed by a solution process, controls microcavity interference and has a characteristic of a light scattering layer,
wherein the quantum dot light emitting device has a top emission structure which emits light from the quantum dot light emitting layer toward a direction where the capping layer is disposed.

2. The quantum dot light emitting device of claim 1, wherein the capping layer includes a plurality of nanoparticles, and the plurality of nanoparticles constitute a plurality of nanoparticle clusters.

3. The quantum dot light emitting device of claim 2, wherein the plurality of nanoparticles include at least one of a metal oxide and a non-metal oxide.

4. The quantum dot light emitting device of claim 2, wherein the plurality of nanoparticles include at least one of zinc oxide, zinc magnesium oxide, zinc aluminum oxide, titanium oxide, and silicon oxide.

5. The quantum dot light emitting device of claim 2,
wherein the capping layer has a distribution factor (ρ) in a range of 0.2 to 5, and the distribution factor (ρ) is defined by an equation ρ=N(A_{cluster}/A_{s-CPL}),
wherein in the equation, A_{cluster} represents an area occupied by the nanoparticle cluster in a cross-sectional region of the capping layer, A_{s-CPL} represents an area occupied by the entire capping layer corresponding to the cross-sectional region, and N represents a number of the nanoparticle cluster in the cross-sectional region.

6. The quantum dot light emitting device of claim 1, wherein the capping layer has a normalized scattering intensity in a range of 1.1 to 1.5.

7. The quantum dot light emitting device of claim 1, wherein the capping layer has a surface roughness (RMS) greater than 0 and less than or equal to 5 nm.

8. The quantum dot light emitting device of claim 1, further comprising at least one of a first charge injection layer disposed between the first electrode and the first charge transport layer, and a second charge injection layer disposed between the second electrode and the second charge transport layer.

9. The quantum dot light emitting device of claim 1,
wherein the quantum dot light emitting layer includes a first quantum dot light emitting portion disposed to correspond to a first pixel region, a second quantum dot light emitting portion disposed to correspond to a second pixel region, and a third quantum dot light emitting portion disposed to correspond to a third pixel region,
wherein the capping layer includes a first capping layer portion disposed to correspond to the first pixel region, a second capping layer portion disposed to correspond to the second pixel region, and a third capping layer portion disposed to correspond to the third pixel region,
wherein at least two of the first to third capping layers have different thicknesses.

10. A manufacturing method of a quantum dot light emitting device comprising:
preparing a first electrode;
forming a first charge transport layer on the first electrode;
forming a quantum dot light emitting layer including quantum dots on the first charge transport layer;
forming a second charge transport layer on the quantum dot light emitting layer;
forming a second electrode on the second charge transport layer; and
forming a capping layer which controls microcavity interference and has a characteristic of a light scattering layer on the second electrode by using a solution process,
wherein the quantum dot light emitting device has top emission characteristic which emits light from the quantum dot light emitting layer toward a direction where the capping layer is disposed.

11. The manufacturing method of a quantum dot light emitting device of claim 10, wherein the capping layer includes a plurality of nanoparticles, and the plurality of nanoparticles constitute a plurality of nanoparticle clusters.

12. The manufacturing method of a quantum dot light emitting device of claim 11, wherein the plurality of nanoparticles include at least one of a metal oxide and a non-metal oxide.

13. The manufacturing method of a quantum dot light emitting device of claim 11, wherein the plurality of nanoparticles include at least one of zinc oxide, zinc magnesium oxide, zinc aluminum oxide, titanium oxide, and silicon oxide.

14. The manufacturing method of a quantum dot light emitting device of claim 11,
wherein the capping layer has a distribution factor (ρ) in a range of 0.2 to 5, and the distribution factor (ρ) is defined by an equation ρ=N(A_{cluster}/A_{s-CPL}),
wherein in the equation, A_{cluster} represents an area occupied by the nanoparticle cluster in a cross-sectional region of the capping layer, A_{s-CPL} represents an area occupied by the entire capping layer corresponding to the cross-sectional region, and N represents a number of the nanoparticle cluster in the cross-sectional region.

15. The manufacturing method of a quantum dot light emitting device of claim 10, wherein the capping layer has a normalized scattering intensity in a range of about 1.1 to 1.5.

16. The manufacturing method of a quantum dot light emitting device of claim 10, wherein the capping layer has a surface roughness (RMS) greater than 0 and less than or equal to 5 nm.

17. The manufacturing method of a quantum dot light emitting device of claim 10, wherein the capping layer is formed by any one of an inkjet printing method, a transfer printing method, and a spin coating method.

18. The manufacturing method of a quantum dot light emitting device of claim 10, further comprising at least one of forming a first charge injection layer between the first electrode and the first charge transport layer, and forming a second charge injection layer between the second electrode and the second charge transport layer.

19. The manufacturing method of a quantum dot light emitting device of claim 10,
wherein the quantum dot light emitting layer includes a first quantum dot light emitting portion disposed to correspond to a first pixel region, a second quantum dot light emitting portion disposed to correspond to a second pixel region, and a third quantum dot light emitting portion disposed to correspond to a third pixel region,
wherein the capping layer includes a first capping layer portion disposed to correspond to the first pixel region, a second capping layer portion disposed to correspond to the second pixel region, and a third capping layer portion disposed to correspond to the third pixel region,
wherein at least two of the first to third capping layers have different thicknesses.
